(19) United States
(12) Patent Application Publication
(10) Pub. No.: US 2025/0116685 A1
(43) Pub. Date: Apr. 10, 2025

(54) PROBE STORAGE JIG, PROBE STORAGE SYSTEM, AND PROBE STORAGE METHOD

(71) Applicant: Kabushiki Kaisha Nihon Micronics, Tokyo (JP)

(72) Inventor: Toshinaga TAKEYA, Aomori (JP)

(21) Appl. No.: 18/709,483

(22) PCT Filed: Oct. 24, 2022
(86) PCT No.: PCT/JP2022/039498

§ 371 Date: Dec. 20, 2024

(30) Foreign Application Priority Data
Nov. 22, 2021 (JP) 2021-189201

(51) Int. Cl. G01R 1/067; G01R 1/073

(52) U.S. Cl. CPC G01R 1/06711; G01R 1/06705; G01R 1/07392

(57) ABSTRACT

A probe storage jig has a structure in which a first guide plate and a second guide plate are stacked. A through-hole penetrating from an upper surface to a lower surface is formed in each of the first guide plate and the second guide plate. The probe storage jig holds the probe penetrating through the through-hole formed in each of the first guide plate and the second guide plate, in a state in which an upper part of the support section is exposed when viewed from above the probe storage jig and a tip end of a free end of the arm is exposed when viewed from below the probe storage jig. The probe storage jig is configured in such a way that the first guide plate and the second guide plate are movable so as to sandwich the probe between the first guide plate and the second guide plate.

### TECHNICAL FIELD

The present invention relates to a probe storage jig, a probe storage system and a probe storage method for storing a probe used for inspecting an inspection object.

### BACKGROUND ART

An electrical connection device having a probe which is brought into contact with an inspection object has been used for inspecting the inspection object such as an integrated circuit. In inspection using the electrical connection device, one end of the probe is brought into contact with an electrode terminal of the inspection object. The other end of the probe is electrically connected to a connection terminal disposed on a circuit substrate of the electrical connection device. The connection terminal is electrically connected to an inspection device such as a tester. Signals can be transmitted and received between the inspection object and the inspection device via a probe.

A probe is stored, for example, in a jig that holds the probe in a stable posture. Hereinafter, the jig that stores the probe is referred to as a “probe storage jig”. The configuration including the probe and the probe storage jig is referred to as a “probe storage system”. When an electrical connection device is assembled by joining the probe to a circuit substrate, the probe is removed from the probe storage jig using a handler or the like. The probe removed from the probe storage jig is joined to the circuit substrate one by one.

### CITATION LIST

Patent Literature: Japanese Patent No. 2846851

### SUMMARY OF THE INVENTION

### Technical Problem

When assembling an electrical connection device, it is desirable to check for defects in a probe before joining the probe to the circuit substrate. An object of the present invention is to provide a probe storage jig, a probe storage system, and a probe storage method with which it is easy to check for defects in the probe.

### Technical Solution

According to an aspect of the present invention, there is provided a probe storage jig that stores a probe including an arm having a cantilever structure and a support section connected to a fixed end of the arm. The probe storage jig has a structure in which a first guide plate and a second guide plate are stacked, and both surfaces of the first guide plate and the second guide plate are defined by an upper surface and a lower surface facing each other. A through-hole penetrating from the upper surface to the lower surface is formed in each of the first guide plate and the second guide plate. The probe storage jig holds the probe penetrating through the through-hole formed in each of the first guide plate and the second guide plate, in a state in which an upper part of the support section is exposed when viewed from above the probe storage jig and a tip end of a free end of the arm is exposed when viewed from below the probe storage jig. The probe storage jig is configured in such a way that the first guide plate and the second guide plate are relatively movable so as to sandwich the probe between the first guide plate and the second guide plate.

### Effect of the Invention

The present invention makes it possible to provide a probe storage jig, a probe storage system, and a probe storage method with which it is easy to check for defects in the probe.

### BRIEF DESCRIPTION OF THE DRAWINGS

FIG. 1 is a schematic diagram illustrating a configuration of a probe storage jig according to an embodiment.

FIG. 2 is a schematic cross-sectional view taken along II-II direction of FIG. 1 illustrating the configuration of the probe storage jig according to the embodiment.

FIG. 3 is a schematic plan view illustrating the configuration of the probe storage jig according to the embodiment.

FIG. 4 is a schematic plan view illustrating an overall configuration of the probe storage jig according to the embodiment.

FIG. 5 is a schematic diagram illustrating a configuration of a probe storage jig in a comparative example.

FIG. 6A is a schematic front view for explaining a probe storage method according to the embodiment (part 1).

FIG. 6B is a schematic cross-sectional view for explaining the probe storage method according to the embodiment (part 1).

FIG. 6C is a schematic plan view for explaining the probe storage method according to the embodiment (part 1).

FIG. 7A is a schematic front view for explaining the probe storage method according to the embodiment (part 2).

FIG. 7B is a schematic cross-sectional view for explaining the probe storage method according to the embodiment (part 2).

FIG. 7C is a schematic plan view for explaining the probe storage method according to the embodiment (part 2).

FIG. 8 is a schematic diagram illustrating a configuration of a probe storage jig according to a modified example of the embodiment.

FIG. 9 is a schematic diagram illustrating an example of a posture of a probe that is stored in the probe storage jig.

### DESCRIPTION OF EMBODIMENTS

Embodiments of the present invention will be described below with reference to the drawings. The same or similar elements illustrated in the drawings are denoted by the same or similar reference numerals. The drawings are illustrated schematically, and it should be noted that the proportions of the thicknesses or lengths of the respective parts and so forth are not drawn to scale. It should also be understood that the relationships or proportions of the dimensions between the respective drawings are different from each other in some elements.

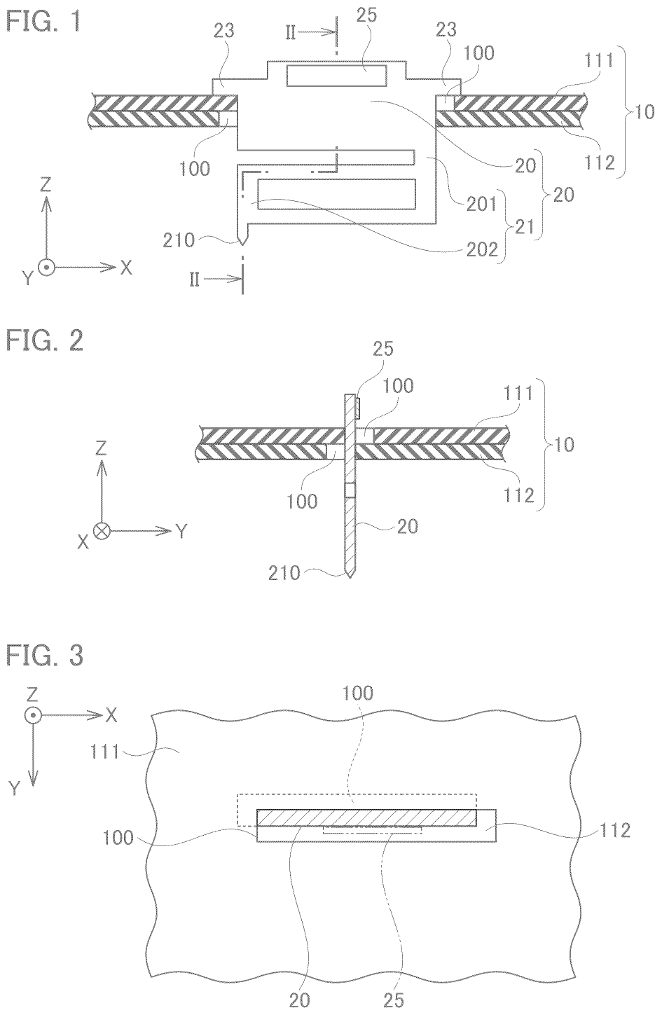

A probe storage jig 10 according to an embodiment of the present invention illustrated in FIG. 1 stores a probe 20 that is used for inspecting an inspection object. As illustrated in FIG. 1, the probe 20 includes an arm 21 having a cantilever structure, and a support section 22 that is connected to a fixed end 201 of the arm 21.

The probe storage jig 10 has a structure in which a first guide plate 111 and a second guide plate 112 are stacked, and both surfaces of the first guide plate 111 and the second guide plate 112 are defined by an upper surface and a lower surface facing each other. A through-hole 100 penetrating from the upper surface to the lower surface is formed in each of the first guide plate 111 and the second guide plate 112.

The probe storage jig 10 holds the probe 20 in a state in which the upper part of the support section 22 is exposed when viewed from above the probe storage jig 10, and the tip end of the free end 202 of the arm 21 is exposed when viewed from below the probe storage jig 10. Here, “when viewed from above the probe storage jig 10” means that the direction of the arm 21 is viewed from the support section 22 of the probe 20. Further, “when viewed from below the probe storage jig 10” means that the direction of the support section 22 is viewed from the arm 21 of the probe 20. More specifically, the probe storage jig 10 holds the probe 20 in a state in which the probe 20 penetrates through each of the through-holes 100 in the first guide plate 111 and the second guide plate 112. In a state in which the probe 20 is stored in the probe storage jig 10, the upper part of the support section 22 of the probe 20 is exposed above the upper surface of the first guide plate 111. The tip end 210 of the free end 202 of the arm 21 of the probe 20 is exposed below the lower surface of the second guide plate 112. The tip end 210 is a portion in contact with the inspection object.

Even if the upper part of the support section 22 is not positioned above the probe storage jig 10, the upper part of the support section 22 may be exposed when viewed from above the probe storage jig 10. Hereinafter, a state in which the upper part of the support section 22 can be observed from the outside is also described as a state in which the upper part of the support section 22 is exposed above the probe storage jig 10. Further, even if the tip end of the free end 202 of the arm 21 is not positioned below the probe storage jig 10, the tip end of the free end 202 may be exposed when viewed from below the probe storage jig 10. Hereinafter, a state in which the tip end of the free end 202 can be observed from the outside is also described as a state in which the tip end of the free end 202 of the arm 21 is exposed below the probe storage jig 10.

Hereinafter, when the guide plate constituting the probe storage jig 10 is not limited to the first guide plate 111 and the second guide plate 112, it will be described as the guide plate(s) 11. Each of the guide plates 11 has the through-hole 100.

As illustrated in FIG. 1, the penetration direction of the through-hole 100, that is, the thickness direction of the guide plate 11, is set in the Z direction. In FIG. 1, the Z direction is the up-down direction in the page space, the X direction is the left-right direction in the page space, and the Y direction is the depth direction in the page space. In the description of the embodiment, the figure viewed from the Y direction is the front view. The front view illustrates a cut surface of the guide plate 11 along the plane surface parallel to the Z direction.

As illustrated in FIG. 1, the support section 22 of the probe 20 is provided with a projection 23 that projects directing outward from the support section 22 when viewed from the Z direction. The projection 23 of the probe 20 stored in the probe storage jig 10 abuts on the upper surface of the first guide plate 111. The projection 23 of the probe 20 functions as a stopper to prevent the probe 20 from falling inside the through-hole 100. In the probe 20 having a plurality of projections 23, each of the projections 23 may be disposed at the same height.

In the probe storage system illustrated in FIG. 1, the projection 23 of the probe 20 abuts on the upper surface of the first guide plate 111, and thus the upper part of the support section 22 is exposed above the upper surface of the first guide plate 111. When the probe storage jig 10 holds the probe 20 with the arm 21 as a downward direction and the support section 22 as an upward direction, the projection 23 is preferably disposed at a position above the center of gravity of the probe 20. Since the projection 23 is positioned above the center of gravity of the probe 20, the position of the center of gravity of the probe 20 is below the position where the probe storage jig 10 supports the probe 20. Since the center of gravity of the probe 20 is below the position where the probe 20 is supported, the probe storage jig 10 can hold the probe 20 in a state in which the probe 20 is in a stable posture.

FIG. 2 is a cross-sectional view of the probe storage jig 10 along the II-II direction of FIG. 1. FIG. 3 is a plan view of the probe storage jig 10 viewed from the Z direction. As illustrated in FIG. 3, the plan view illustrates a cross section along the XY plane surface of the probe 20 at a position below the projection 23 (the same shall apply hereinafter). In the plan view, the through-hole 100 of the second guide plate 112 is illustrated as dashed lines transparently. The probe storage jig 10 is configured in such a way that the first guide plate 111 and the second guide plate 112 are relatively movable in a direction intersecting the penetration direction of the through-hole 100, although the details thereof will be described later. For example, the probe storage jig 10 is configured in such a way that the first guide plate 111 and the second guide plate 112 are relatively movable on the XY plane surface that is a direction perpendicular to the penetration direction of the through-hole 100. As the first guide plate 111 and the second guide plate 112 move, the probe 20 is sandwiched between the inner wall surface of the through-hole 100 of the first guide plate 111 and the inner wall surface of the through-hole 100 of the second guide plate 112.

In a plan view viewed from the penetration direction, the probe 20 has a rectangular shape. In a plan view, the through-hole 100 has a rectangular shape. In a plan view, the outer shape of the probe 20 and the shape of the through-hole 100 may be similar to each other. As illustrated in FIG. 1 to FIG. 3, two adjacent sides of the probe 20 abut on the inner wall surface of the through-hole 100 of the first guide plate 111. Further, two other adjacent sides of the probe 20 abut on the inner wall surface of the through-hole 100 of the second guide plate 112.

That is, the four sides of the probe 20 facing the inner wall surface of the through-hole 100 abut on either the inner wall surface of the through-hole 100 of the first guide plate 111 or the inner wall surface of the through-hole 100 of the second guide plate 112. The four sides of the probe 20 abut on the inner wall surface of the through-hole 100, thereby making it possible for the probe storage jig 10 to hold the probe 20 stably.

A fixing agent 25 is disposed on the side surface of the support section 22 of the probe 20. For example, in the step of assembling an electrical connection device using a solder material as the fixing agent 25, the upper surface of the support section 22 of the probe 20 is joined to the circuit substrate by reflow soldering. Since the support section 22 is joined to the electrode terminal of the circuit substrate by the fixing agent 25, the probe 20 is electrically connected to the circuit pattern formed on the circuit substrate. By exposing the portion where the fixing agent 25 is disposed above the probe storage jig 10, the state of the fixing agent 25 can be observed in a state in which the probe 20 is stored in the probe storage jig 10.

In a case where the upper surface of the support section 22 is a region joined to the circuit substrate, the fixing agent 25 may be disposed at a portion where the upper part of the support section 22 is partially extended in the Z direction (hereinafter, referred to as an “extension portion”) as illustrated in FIG. 1. Hereinafter, the region joined to the circuit substrate of the probe 20 is also referred to as a “joint portion”. In the probe 20 illustrated in FIG. 1, the upper surface of the extension portion is a joint portion. The fixing agent 25 is disposed on the side surface of the extension portion, thereby making it possible for the solder material to flow around the upper surface of the extension portion when performing reflow soldering. Since the solder material flows around the joint portion, spreading of the fixing agent 25 on the circuit substrate can be suppressed.

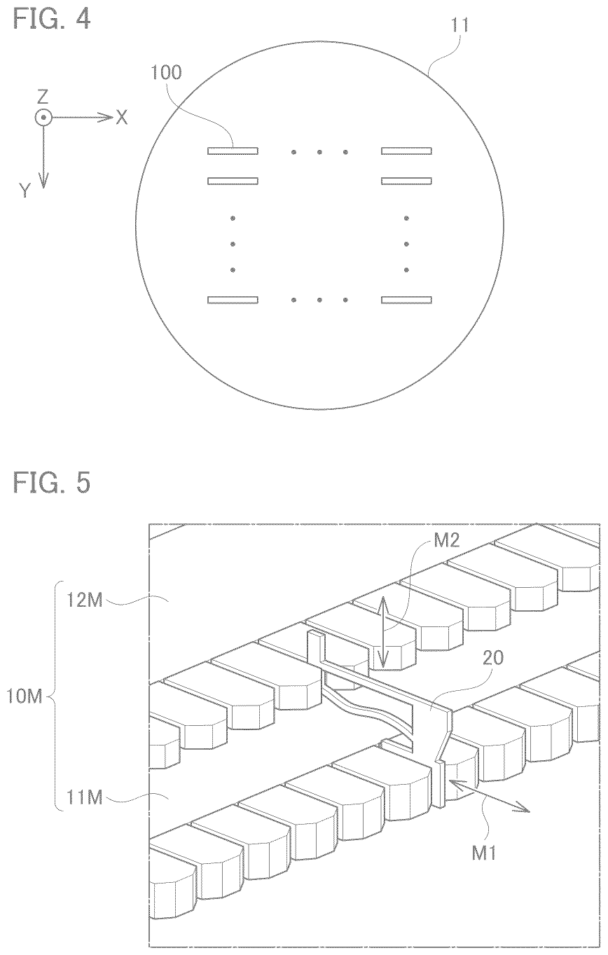

A plurality of probes 20 can be stored in one probe storage jig 10. For example, as illustrated in FIG. 4, a plurality of through-holes 100 may be formed in the disc-shaped guide plate 11. The probe 20 is inserted into each of the plurality of through-holes 100 formed in the guide plate 11, and thus the probe storage jig 10 stores the plurality of probes 20. The through-holes 100 formed in the guide plate 11 can be optionally arranged according to a desired layout.

In the probe storage system illustrated in FIG. 1, the upper part of the support section 22 of the probe 20 is exposed above the probe storage jig 10. For this reason, when the upper surface of the support section 22 is a joint portion which is joined to the circuit substrate, the state of the joint portion of the probe 20 can be observed in a state in which the probe 20 is stored in the probe storage jig 10. Accordingly, if a defect occurs in the joint portion which makes it difficult to join the probe 20 to the circuit substrate, the defect in the joint portion can be detected prior to the step of assembling the electrical connection device. For example, the probe 20 having a defect in the joint portion, or the probe 20 having an insufficient amount of the fixing agent 25 for joining can be excluded from the step of assembling the electrical connection device.

In the probe storage system illustrated in FIG. 1, the tip end 210 of the arm 21 of the probe 20 is exposed below the probe storage jig 10. For this reason, the state of the tip end 210 of the arm 21 of the probe 20 can be observed in a state in which the probe 20 is stored in the probe storage jig 10. Accordingly, if a defect occurs in the arm 21 which makes it difficult for the tip end 210 to be brought into contact with the inspection object, the defect in the arm 21 can be detected prior to the step of assembling the electrical connection device. For example, the probe 20 in which the tip end 210 of the arm 21 is bent or broken can be excluded from the step of assembling the electrical connection device.

For making a comparison with the probe storage system illustrated in FIG. 1, a case will be described below in which the probe 20 is stored in a comparison probe storage jig 10M illustrated in FIG. 5 The comparison probe storage jig 10M includes a first slit plate 11M and a second slit plate 12M. The first slit plate 11M and the second slit plate 12M each have comb-shaped slits.

When the probe 20 is stored in the comparison probe storage jig 10M, the probe 20 is inserted into the slit of the first slit plate 11M and the slit of the second slit plate 12M, for example, as illustrated by arrows M1 and M2 in FIG. 5. The support section 22 of the probe 20 is held in the slit of the first slit plate 11M with the tip end 210 of the arm 21 of the probe 20 facing upward. The arm 21 of the probe 20 is then held in the slit of the second slit plate 12M.

Accordingly, in a state in which the probe 20 is stored in the comparison probe storage jig 10M, the joint portion of the probe 20 cannot be observed. Since the joint portion cannot be observed, the defect in the joint portion of the probe 20 cannot be detected until after the probe 20 is removed from the comparison probe storage jig 10M. Further, the probe 20 is held in the slit of the first slit plate 11M and in the slit of the second slit plate 12M by the self-weight of the probe 20. For this reason, in order to stably carry the probe 20 stored in the comparison probe storage jig 10M, a mechanism for fixing the probe 20 to the comparison probe storage jig 10M is necessary.

In contrast, in the probe storage system using the probe storage jig 10, the joint portion of the probe 20 is exposed above the probe storage jig 10, and the tip end 210 of the arm 21 of the probe 20 is exposed below the probe storage jig 10. For this reason, the joint portion and the tip end 210 of the probe 20 can be observed in a state in which the probe 20 is stored in the probe storage jig 10. Further, the center of gravity of the probe 20 is below the position where the probe storage jig 10 supports the probe 20. Since the center of gravity of the probe 20 is below the position described above, the posture of the probe 20, which is stored in the probe storage jig, 10 is stabilized. For this reason, the probe 20 stored in the probe storage jig 10 can be carried in a stable posture without fixing the probe 20 to the probe storage jig 10.

As described above, the probe storage jig 10 according to the embodiment stores the probe 20 in a state in which the joint portion of the probe 20 and the tip end 210 of the arm 21 are exposed. Accordingly, the probe storage jig 10 makes it easy to check for defects in the probe.

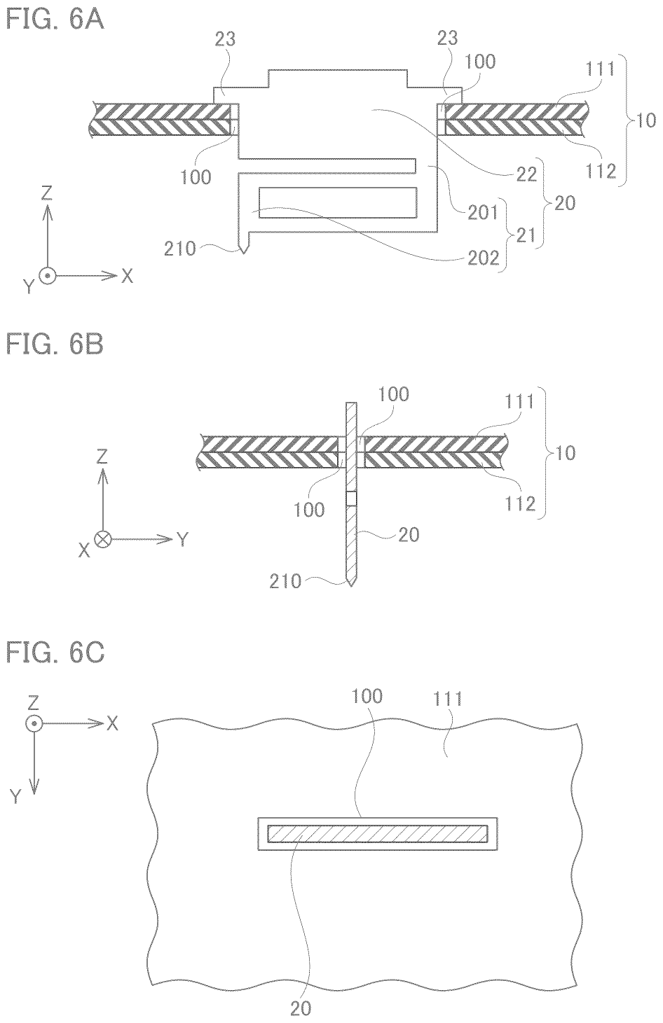

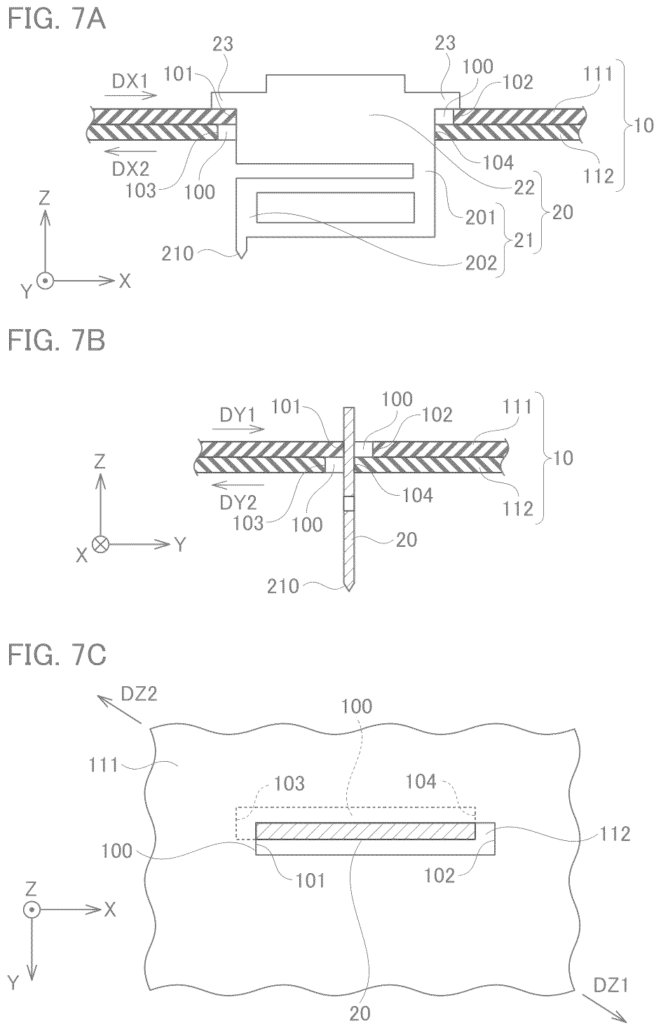

With reference to FIGS. 6A, 6B, and 6C, and FIGS. 7A, 7B, and 7C, an example of a probe storage method will be described below in which the probe 20 is stored in the probe storage jig 10. FIGS. 6A and 7A are front views, FIGS. 6B and 7B are cross-sectional views along the II-II direction of FIG. 1, and FIGS. 6C and 7C are plan views which are viewed from the Z direction. FIGS. 6A, 6B, and 6C and FIGS. 7A, 7B, and 7C do not illustrate the fixing agent 25.

First, the probe storage jig 10 and the probe 20 are prepared. As illustrated in FIGS. 6A, 6B, and 6C, the probe storage jig 10 is caused to match the position of the through-hole 100 of the first guide plate 111 to the position of the through-hole 100 of the second guide plate 112 when viewed from the Z direction. The probe 20 is then inserted into the respective through-holes 100 of the first guide plate 111 and the second guide plate 112. Specifically, the probe 20 is inserted into the through-holes 100 from the upper surface side of the first guide plate 111 until the projections 23 formed in the support section 22 abut on the upper surface of the first guide plate 111.

When the probe 20 is inserted into the through-holes 100 until the projections 23 abut on the upper surface of the first guide plate 111, the upper part of the support section 22 is exposed above the upper surface of the first guide plate 111. The tip end 210 of the free end 202 of the arm 21 is then exposed below the lower surface of the second guide plate 112.

Next, as illustrated in FIGS. 7A, 7B, and 7C, the first guide plate 111 and the second guide plate 112 are relatively moved to a direction intersecting the penetration direction (Z direction) of the through-holes 100. For example, as illustrated in FIG. 7A, in the X direction, the first guide plate 111 is moved to the right direction of the page space as illustrated by the arrow DX1, and the second guide plate 112 is moved to the left direction of the page space as illustrated by the arrow DX2. In the Y direction, the first guide plate 111 is moved to the right direction of the page space as illustrated by the arrow DY1, and the second guide plate 112 is moved to the left direction of the page space as illustrated by the arrow DY2. That is, as illustrated in FIG. 7C, on the XY plane surface, the first guide plate 111 is moved to the lower right direction of the page space as illustrated by the arrow DZ1, and the second guide plate 112 is moved to the upper left direction of the page space as illustrated by the arrow DZ2. One of the positions of the first guide plate 111 and the second guide plate 112 may be fixed, and the other position may be moved.

As the first guide plate 111 moves relatively with respect to the probe 20, the first inner wall surface 101 of the through-hole 100 of the first guide plate 111 abuts on the probe 20. Meanwhile, the second inner wall surface 102 facing the first inner wall surface 101 is separated from the probe 20. Further, as the second guide plate 112 moves relatively with respect to the probe 20, the third inner wall surface 103 of the second guide plate 112 in the same direction as the first inner wall surface 101 is separated from the probe 20, and the fourth inner wall surface 104 facing the third inner wall surface 103 abuts on the probe 20.

By moving the first guide plate 111 and the second guide plate 112 on the XY plane surface as described above, the probe 20 is sandwiched between the first guide plate 111 and the second guide plate 112. That is, the probe 20 is sandwiched between the inner wall surface of the through-hole 100 of the first guide plate 111 and the inner wall surface of the through-hole 100 of the second guide plate 112. The probe storage jig 10 fixes the position of the probe 20 by sandwiching the probe 20 with the guide plates 11.

According to the probe storage method described above, the probe 20 is stored in the probe storage jig 10 in a state in which the joint portion of the probe 20 and the tip end 210 of the arm 21 are exposed. Accordingly, the probe storage method according to the embodiment makes it possible to easily check for defects in the probe.

### Modified Example

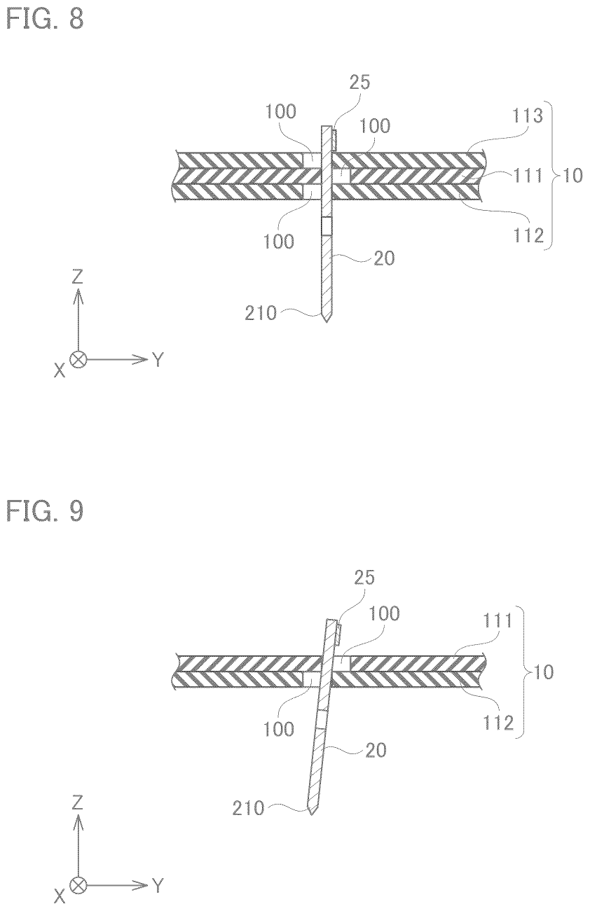

In the above description, an example has been described in which the probe storage jig 10 include two guide plates 11. However, the probe storage jig 10 may include three or guide plates 11. For example, as illustrated in FIG. 8, the probe storage jig 10 may further have a third guide plate 113. The third guide plate 113 is stacked on a stacked body of the first guide plate 111 and the second guide plate 112. Through-holes 100 through which a probe 20 penetrates are formed in the third guide plate 113. The third guide plate 113 is relatively movable with respect to the first guide plate 111 and the second guide plate 112 in a direction intersecting the penetration direction.

For example, as illustrated in FIG. 9, the probe 20 sandwiched between the first guide plate 111 and the second guide plate 112 is inclined in the Z direction and stored in the probe storage jig 10 in some cases. The probe storage jig 10 having the third guide plate 113 can adjust the posture of the probe 20 which is inclined and sandwiched between the first guide plate 111 and the second guide plate 112.

That is, in the state illustrated in FIG. 9, the third guide plate 113 is moved on the XY plane surface relatively with respect to the first guide plate 111 and the second guide plate 112. Specifically, the third guide plate 113 is moved to the side surface of the probe 20, which is sandwiched between the first guide plate 111 and the second guide plate 112, in such a way as to apply pressing force to a direction which corrects the inclination of the probe 20. According to the probe storage jig 10 illustrated in FIG. 8, the posture of the probe 20, which is held in the probe storage jig 10, can also be adjusted by moving the third guide plate 113 as described above.

### Other Embodiments

The embodiment of the present invention have been described above, but the statements and drawings forming part of this disclosure should not be understood as limiting the invention. Various alternative embodiments, examples, and operating techniques will be apparent to those skilled in the art from this disclosure.

For example, an example has been described in which the probe storage jig 10 stores the probe 20 having the projection 23 as a stopper abutting on the upper surface of the first guide plate 111. However, the probe 20 may not have the projection 23. That is, the probe 20 without such a stopper is inserted into the through-hole 100 of the probe storage jig 10, thereby stabilizing the position of the probe 20. At this time, the probe storage jig 10 holds the probe 20 in a state in which the upper part of the support section 22 is exposed above the probe storage jig 10 and the tip end 210 is exposed below the probe storage jig 10. The guide plate 11 is then moved, thereby fixing the position of the probe 20.

It should be understood that the present invention includes various embodiments not described herein. The technical scope of the present invention is determined only by the features according to the claims proper from the above description.

### REFERENCE SIGNS LIST

10: Probe storage jig
11: Guide plate
20: Probe
21: Arm
22: Support section
25: Fixing agent
100: Through-hole
101: First inner wall surface
102: Second inner wall surface
103: Third inner wall surface
104: Fourth inner wall surface
111: First guide plate
112: Second guide plate
113: Third guide plate
201: Fixed end
202: Free end
210: Tip end

1. A probe storage jig that stores a probe including an arm having a cantilever structure and a support section connected to a fixed end of the arm, wherein
the probe storage jig has a structure in which a first guide plate and a second guide plate are stacked, and both surfaces of the first guide plate and the second guide plate are defined by an upper surface and a lower surface facing each other, and in which a through-hole penetrating from the upper surface to the lower surface is formed in each of the first guide plate and the second guide plate,
the probe storage jig holds the probe penetrating through the through-hole formed in each of the first guide plate and the second guide plate, in a state in which an upper part of the support section is exposed when viewed from above the probe storage jig and a tip end of a free end of the arm is exposed when viewed from below the probe storage jig, and
the probe storage jig is configured in such a way that the first guide plate and the second guide plate are relatively movable in a direction perpendicular to a penetration direction of the through-hole so as to sandwich the probe between the first guide plate and the second guide plate.

2. The probe storage jig according to claim 1, wherein
a projection projecting from the support section abuts on the upper surface of the first guide plate.

3. The probe storage jig according to claim 1, wherein
two adjacent sides of the probe abut on an inner wall surface of the through-hole of the first guide plate, and
two other adjacent sides of the probe abut on an inner wall surface of the through-hole of the second guide plate.

4. The probe storage jig according to claim 1, further comprising:
a third guide plate that is stacked on a stacked body of the first guide plate and the second guide plate and in which the through-hole through which the probe penetrates is formed,
wherein the third guide plate is relatively movable with respect to the first guide plate and the second guide plate in a direction intersecting the penetration direction.

5. A probe storage system including a probe that is used for inspecting an inspection object and a probe storage jig that stores the probe, the system comprising:
the probe that includes an arm having a cantilever structure and a support section connected to a fixed end of the arm, and is provided with a projection projecting from the support section; and
the probe storage jig having a structure in which a first guide plate and a second guide plate are stacked, and both surfaces of the first guide plate and the second guide plate are defined by an upper surface and a lower surface facing each other, and in which a through-hole penetrating from the upper surface to the lower surface is formed in each of the first guide plate and the second guide plate, wherein
the probe storage jig holds the probe penetrating through the through-hole formed in each of the first guide plate and the second guide plate,
the projection of the probe abuts on the upper surface of the first guide plate,
an upper part of the support section is exposed when viewed from above the probe storage jig,
a tip end of a free end of the arm is exposed when viewed from below the probe storage jig, and
the probe storage jig is configured in such a way that the first guide plate and the second guide plate are relatively movable in a direction perpendicular to a penetration direction of the through-hole, and the probe is sandwiched between the first guide plate and the second guide plate.

6. The probe storage system according to claim 5, wherein
two adjacent sides of the probe abut on an inner wall surface of the through-hole of the first guide plate, and
two other adjacent sides of the probe abut on an inner wall surface of the through-hole of the second guide plate.

7. The probe storage system according to claim 5, wherein
when the probe storage jig holds the probe with the arm as a downward direction and the support section as an upward direction, the projection is disposed at a position above center of gravity of the probe.

8. The probe storage system according to claim 5, wherein
the probe storage jig further includes a third guide plate that is stacked on a stacked body of the first guide plate and the second guide plate and in which the through-hole through which the probe penetrates is formed,
the third guide plate is relatively movable with respect to the first guide plate and the second guide plate in a direction intersecting the penetration direction.

9. A probe storage method for storing a probe that is used for inspecting an inspection object in a probe storage jig, the method comprising:
preparing the probe including an arm having a cantilever structure and a support section connected to a fixed end of the arm;
preparing the probe storage jig having a structure in which a first guide plate and a second guide plate are stacked, and both surfaces of the first guide plate and the second guide plate are defined by an upper surface and a lower surface facing each other, and in which a through-hole penetrating from the upper surface to the lower surface is formed in each of the first guide plate and the second guide plate;
inserting the probe into the through-hole formed in each of the first guide plate and the second guide plate such that an upper part of the support section is exposed when viewed from above the probe storage jig and a tip end of a free end of the arm is exposed when viewed from below the probe storage jig; and
moving the first guide plate and the second guide plate relatively in a direction perpendicular to a penetration direction of the through-hole, and holding the probe by means of the probe storage jig in a state in which the probe is sandwiched between the first guide plate and the second guide plate.

10. The probe storage method according to claim 9, further comprising:
causing a projection projecting from the support section to abut on the upper surface of the first guide plate.

11. The probe storage method according to claim 9, further comprising:
preparing the probe storage jig further including a third guide plate that is stacked on a stacked body of the first guide plate and the second guide plate and in which the through-hole through which the probe penetrates is formed; and
moving the third guide plate relatively with respect to the first guide plate and the second guide plate in a direction perpendicular to the penetration direction, and adjusting a posture of the probe in a state that is sandwiched between the first guide plate and the second guide plate.
